(19) United States
(12) Patent Application Publication
(10) Pub. No.: US 2025/0248312 A1
(43) Pub. Date: Jul. 31, 2025

(54) MONOLITHICALLY INTEGRATED REMNANT MAGNETIC FIELD AND GRADIENT GENERATION IN ION TRAPS

(71) Applicant: Quantinuum LLC, Broomfield, CO (US)

(72) Inventors: David A. Deen, Edina, MN (US); Timothy Peterson, Broomfield, CO (US); Grahame Vittorini, St. Louis Park, MN (US); Bryce Bjork, Boulder, CO (US); Todd Michael Klein, Wayzata, MN (US)

(21) Appl. No.: 19/035,571

(22) Filed: Jan. 23, 2025

Related U.S. Application Data
(60) Provisional application No. 63/625,388, filed on Jan. 26, 2024.

(51) Int. Cl. H10N 50/01; G06N 10/40; H01F 7/02

(52) U.S. Cl. CPC H10N 50/01; G06N 10/40; H01F 7/0278

(57) ABSTRACT

Various examples in accordance with the present disclosure provide a ferromagnet-integrated atomic object confinement apparatus. Some embodiments include a confinement region, a first layer of a plurality of layers comprising one or more electrodes configured to generate a confining potential configured to confine one or more atomic objects in the confinement region at an atomic object elevation associated with the confinement region, and at least one ferromagnetic film integrated with the plurality of layers, the at least one ferromagnetic film configured to apply magnetic fields and magnetic field gradients to the one or more atomic objects.

### CROSS-REFERENCE TO RELATED APPLICATIONS

This application claims priority to U.S. Provisional Patent Application No. 63/625,388, filed on Jan. 26, 2024, which is incorporated herein by reference in its entirety.

### TECHNICAL FIELD

Various embodiments relate to apparatuses, systems, and methods, relating to atomic object confinement devices. An example embodiment relates to monolithically integrated remanent magnetic field and gradient generation by ferromagnetic films in atomic object confinement apparatuses.

### BACKGROUND

In several contexts, atomic object confinement apparatuses are leveraged to trap atomic objects and manipulate the atomic objects to perform various functions. Applicant has discovered problems associated with interacting with trapped atomic objects in atomic object confinement apparatuses. Through applied effort, ingenuity, and innovation, Applicant has solved many of the identified problems by developing the embodiments of the present disclosure, many examples of which are described in detail below.

### BRIEF SUMMARY

In general, embodiments of the present disclosure herein relate to monolithically integrated remanent magnetic field and gradient generation by ferromagnetic films in atomic object confinement apparatuses. In accordance with one aspect of the present disclosure a ferromagnet-integrated atomic object confinement apparatus. In some embodiments, the ferromagnet-integrated atomic object confinement apparatus comprises a confinement region; a first layer of a plurality of layers comprising one or more electrodes configured to generate a confining potential configured to confine one or more atomic objects in the confinement region at an atomic object elevation associated with the confinement region; and at least one ferromagnetic film integrated with the plurality of layers, the at least one ferromagnetic film configured to apply magnetic fields and magnetic field gradients to the one or more atomic objects.

In some embodiments, the at least one ferromagnetic film is configured to generate a quantization magnetic field that separates electronic states in a ground state manifold of magnetically-sensitive ions.

In some embodiments, the at least one ferromagnetic film comprises a plurality of permanent magnets associated with the first layer.

In some embodiments, the plurality of permanent magnets comprise a planar Halbach array.

In some embodiments, the plurality of permanent magnets define a magnetic orientation parallel to a plane defined by the first layer and rotated at an angle relative to an axis of the first layer to provide the magnetic field.

In some embodiments, the plurality of permanent magnets comprise a first permanent magnet and a second permanent magnet that border the one or more electrodes.

In some embodiments, the confinement region comprises one or more interaction zones, wherein the plurality of permanent magnets are positioned in the one or more interaction zones.

In some embodiments, one or more ferromagnetic films are disposed in one or more subsequent layers with respect to the first layer.

In some embodiments, further comprising an interposer, wherein the at least one ferromagnetic film comprises a plurality of permanent magnets disposed in the interposer.

In some embodiments, the first layer defines a surface of the ferromagnet-integrated atomic object confinement apparatus.

In accordance with another aspect of the present disclosure, a quantum computing system is provided. In one example, the quantum computing system comprises a ferromagnet-integrated atomic object confinement apparatus comprising: a confinement region; a first layer of a plurality of layers comprising one or more electrodes configured to generate a confining potential configured to confine one or more atomic objects in the confinement region at an atomic object elevation associated with the confinement region; and at least one ferromagnetic film integrated with the plurality of layers, the at least one ferromagnetic film configured to apply magnetic fields and magnetic field gradients to the one or more atomic objects.

In some embodiments, the at least one ferromagnetic film is configured to generate a quantization magnetic field that separates electronic states in a ground state manifold of magnetically-sensitive ions.

In some embodiments, the at least one ferromagnetic film comprises a plurality of permanent magnets associated with the first layer.

In some embodiments, the plurality of permanent magnets comprise a planar Halbach array.

In some embodiments, the plurality of permanent magnets define a magnetic orientation parallel to a plane defined by the first layer and rotated at an angle relative to an axis of the first layer to provide the magnetic field.

In some embodiments, the plurality of permanent magnets comprise a first permanent magnet and a second permanent magnet that border the one or more electrodes.

In some embodiments, the confinement region comprises one or more interaction zones, wherein the plurality of permanent magnets are positioned in the one or more interaction zones.

In some embodiments, one or more ferromagnetic films are disposed in one or more subsequent layers with respect to the first layer.

In accordance with another aspect of the present disclosure, a method of fabricating a ferromagnet-integrated atomic object confinement apparatus is provided. In one example, the method comprises depositing one or more layers on a substrate; depositing a top layer on the one or more layers, the top layer comprising one or more electrodes; and depositing at least one ferromagnetic film.

In some embodiments, depositing the at least one ferromagnetic film comprises performing one or more of magnetron sputtering, atomic layer deposition, electron beam deposition, ion beam deposition, electroplating, or epitaxy.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1 is a schematic diagram illustrating an example quantum computing system comprising a ferromagnet-integrated atomic object confinement apparatus in accordance with at least one example embodiment.

FIG. 2a provides a cross section of at least a portion of a ferromagnet-integrated atomic object confinement apparatus in accordance with at least one example embodiment.

FIG. 2b provides a cross section of at least a portion of a ferromagnet-integrated atomic object confinement apparatus in accordance with at least one example embodiment.

FIG. 3a provides an on-axis ferromagnet integration in accordance with at least one example embodiment.

FIG. 3b provides on-axis ferromagnet integration in accordance with at least one example embodiment.

FIG. 4a provides an example off-axis ferromagnet integration in accordance with at least one example embodiment.

FIG. 4b provides an example canted-axis ferromagnet integration in accordance with at least one example embodiment.

FIG. 4c provides a magnetic field and gradient plot in accordance with at least one example embodiment.

FIG. 5 provides a flowchart illustrating operations for ferromagnet-integrated atomic object confinement apparatus in accordance with one example embodiment.

FIG. 6 provides a schematic diagram of an example controller of a quantum computer that may be used in accordance with an example embodiment.

FIG. 7 provides a schematic diagram of an example computing entity of a quantum computer system that may be used in accordance with an example embodiment.

### DETAILED DESCRIPTION

The present invention now will be described more fully hereinafter with reference to the accompanying drawings, in which some, but not all embodiments of the invention are shown. Indeed, the invention may be embodied in many different forms and should not be construed as limited to the embodiments set forth herein; rather, these embodiments are provided so that this disclosure will satisfy applicable legal requirements. The term “or” (also denoted “/”) is used herein in both the alternative and conjunctive sense, unless otherwise indicated. The terms “illustrative” and “exemplary” are used to be examples with no indication of quality level. The terms “generally” and “approximately” refer to within engineering and/or manufacturing limits and/or within user measurement capabilities, unless otherwise indicated. Like numbers refer to like elements throughout.

Example embodiments provide apparatuses, systems, and methods that relate to atomic object confinement apparatus comprising ferromagnetic film(s). In various embodiments, a ferromagnet-integrated atomic object confinement apparatus system comprises a confinement apparatus configured for confining atomic objects and an integrated signal management system, where at least a portion of the signal management system is disposed on the same substrate and/or chip as the electrical components (e.g., electrodes) of the confinement apparatus. The electrodes, for example, may be configured for defining confinement regions within which atomic objects may be confined.

In various embodiments, the signal management system includes one or more manipulation elements. In various embodiments, the one or more manipulation elements comprise one or more ferromagnetic films and one or more laser systems (e.g., UV lasers, visible lasers, microwave lasers, and/or the like). In various embodiments, the one or more ferromagnetic films are configured to generate and apply magnetic fields and magnetic field gradients to atomic objects to perform various functions, including manipulation of quantum states in atomic objects. The one or more lasers may provide one or more laser beams to the ferromagnet-integrated atomic object confinement apparatus 120. The one or more lasers may be configured to provide one or more manipulation signals configured to manipulate and/or cause a controlled quantum state evolution of one or more atomic objects within the ferromagnet-integrated atomic object confinement apparatus 120.

Example embodiments integrate thin magnetic films within the ferromagnet-integrated atomic object confinement apparatus to generate magnetic fields that separates electronic states in a ground state manifold of magnetically-sensitive ions. For example, the magnetic films may produce quantization magnetic fields that separates Zeeman states from clock (e.g., magnetic field insensitive) states in the ground state of magnetically-sensitive ions (e.g., ions with non-zero magnetic moment). In various embodiments, a magnetic film layer comprises one or more permanent magnets. For example, example embodiments integrate magnetic films that comprise strong remanent permanent magnet films into the ferromagnet-integrated atomic object confinement apparatus to produce magnetic fields and magnetic field gradients that enable motional mode coupling (e.g., interaction with ions and/or or manipulation of quantum states). In this regard, various embodiments monolithically integrate remanent magnetic field and gradient generation (e.g., generated by ferromagnetic films) into an atomic object confinement apparatus.

In some examples, the ferromagnetic film(s) are disposed on a surface of the ferromagnet-integrated atomic object confinement apparatus and/or at least partially within a substrate on which the ferromagnet-integrated atomic object confinement apparatus is formed. For example, the ferromagnet-integrated atomic object confinement apparatus may be formed on a substrate with at least one ferromagnetic film formed and/or disposed on a surface of the substrate. The substrate may comprise multiple layers of circuitry configured to control various elements/components of the operation of the functioning of the ferromagnet-atomic object confinement apparatus. In various embodiments, one or more ferromagnetic films may be integrated within any chip stack element, including the ion trap (e.g., top surface and bottom surface regions thereof), interposer, subsequent layers, spacers, and/or package.

### Example Quantum Computing System Comprising a Ferromagnet-Integrated Atomic Object Confinement Apparatus

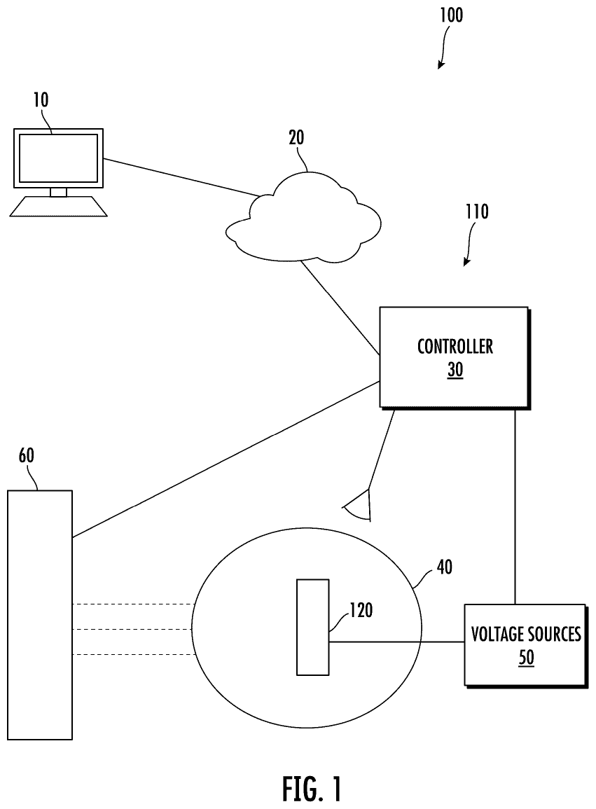

FIG. 1 provides a schematic diagram of an example quantum computing system 100 comprising a ferromagnet-integrated atomic object confinement apparatus 120 (e.g., an ion trap and/or the like), in accordance with an example embodiment. In various embodiments, the quantum computing system 100 includes a signal management system. In various embodiments, the signal management system comprises on or more manipulation elements. In various embodiments, the one or more manipulation elements are formed and/or disposed on and/or in the ferromagnet-integrated atomic object confinement apparatus 120. In various embodiments, at least a portion of the manipulation elements formed and/or disposed in and/or on the ferromagnet-integrated atomic object confinement apparatus 120 are configured to generate magnetic fields and magnetic field gradients that enable motional mode coupling (e.g., manipulation of quantum states in ions/atoms through interactions with the magnetic fields and/or magnetic field gradients).

In various embodiments, the quantum computing system 100 comprises a computing entity 10 and a quantum computer 110. In various embodiments, the quantum computer 110 comprises a controller 30, a cryogenic and/or vacuum chamber 40 enclosing a ferromagnet-integrated atomic object confinement apparatus 120 (e.g., an ion trap). In various embodiments, the cryogenic and/or vacuum chamber 40 is a temperature and/or pressure-controlled chamber. For example, the quantum computing system 100 may comprise vacuum and/or temperature control components that are operatively coupled to the cryogenic and/or vacuum chamber 40.

In various embodiments, the quantum computer 110 comprises one or more voltage sources 50. For example, the voltage sources 50 may comprise a plurality of voltage drivers and/or voltage sources and/or at least one RF driver and/or voltage source. The voltage sources 50 may be electrically coupled to the corresponding electrode elements (e.g., electrodes) of the confinement apparatus, in an example embodiment.

In various embodiments, a computing entity 10 is configured to allow a user to provide input to the quantum computer 110 (e.g., via a user interface of the computing entity 10) and receive, view, and/or the like output from the quantum computer 110. The computing entity 10 may be in communication with the controller 30 of the quantum computer 110 via one or more wired or wireless networks 20 and/or via direct wired and/or wireless communications. In an example embodiment, the computing entity 10 may translate, configure, format, and/or the like information/data, quantum computing algorithms and/or circuits, and/or the like into a computing language, executable instructions, command sets, and/or the like that the controller 30 can understand and/or implement.

In various embodiments, the controller 30 is configured to control and/or in electrical communication with the voltage sources 50, cryogenic system and/or vacuum system controlling the temperature and/or pressure within the cryogenic and/or vacuum chamber 40, manipulation sources, and/or other systems controlling various environmental conditions (e.g., temperature, pressure, and/or the like) within the cryogenic and/or vacuum chamber 40 and/or configured to manipulate and/or cause a controlled evolution of quantum states of one or more quantum objects within the confinement apparatus. For example, the controller 30 may cause a reading procedure comprising coherent shelving to be performed, possibly as part of executing a quantum circuit and/or algorithm. In various embodiments, the atomic objects confined within the confinement apparatus are used as qubits of the quantum computer 110.

In various embodiments, the ferromagnet-integrated atomic object confinement apparatus 120 is a confinement apparatus configured to confine one or more atomic objects therein and generate, using the manipulation elements integrated therein, magnetic fields and/or magnetic field gradients that may be leveraged for manipulating quantum states of the atomic objects. An example of an atomic object is an ion. In various embodiments, the manipulation elements may be used to initialize one or more atomic objects into a qubit space, perform cooling operations, perform measurement operations, provide one or more gate signals, and/or the like. In various embodiments, the manipulation elements comprise ferromagnetic films (e.g., thin permanent magnets) and one or more laser systems (e.g., UV lasers, visible lasers, microwave lasers, and/or the like). For example, the lasers may provide one or more laser beams to the ferromagnet-integrated atomic object confinement apparatus 120. The one or more lasers may be configured to provide one or more manipulation signals configured to manipulate and/or cause a controlled quantum state evolution of one or more ions within the ferromagnet-integrated atomic object confinement apparatus 120.

### Example Ferromagnet-Integrated Atomic Object Confinement Apparatus

In various embodiments, the ferromagnet-integrated atomic object confinement apparatus 120 comprises a plurality of electrical components, such as electrodes, that are configured to generate a confining potential. In various embodiments, the electrodes of the ferromagnet-integrated atomic object confinement apparatus 120 are formed and/or disposed in and/or on a confinement apparatus substrate or chip. For example, the controller 30 may control the voltage sources 50 to provide electrical signals to the electrodes of the atomic object confinement apparatus such that the electrodes generate a confining potential. The confining potential is configured to confine a plurality of atomic objects within a confinement volume (e.g., confinement region) defined by the atomic object confinement apparatus. For example, in an example embodiment, the atomic object confinement apparatus 120 is a surface ion trap, and the confinement volume is a volume located proximate the surface of the surface ion trap. In various embodiments, the atomic object confinement apparatus 120 is a multi-layered ion trap and the confinement volume is volume located proximate the uppermost layer (e.g., top layer) of the multi-layered ion trap. In various embodiments, the electrodes and/or confining potential are configured to define a plurality of atomic object positions within the confinement volume.

In various embodiments, the atomic object positions are disposed in a one-dimensional or multi-dimensional layout. For example, in an example embodiment, the atomic object positions are disposed along an axis of a linear atomic object confinement apparatus. In another example embodiment, the atomic object positions are disposed in a two-dimensional array or layout defined by a two-dimensional atomic object confinement apparatus. In another example embodiments, the atomic object positions are disposed in a three-dimensional layout defined by a three-dimensional atomic object confinement apparatus.

In various embodiments, the voltage sources 50 provide electrical signals to the potential generating elements (e.g., electrodes) of the ferromagnet-integrated atomic object confinement apparatus 120, such that a confining potential is formed. Based on the contours and time evolution of the confining potential, one or more atomic objects are confined at respective atomic object positions, moved between atomic object positions and/or the like. When an atomic object is located at an atomic object position, one or more functions (e.g., quantum computing functions) may be performed on the atomic object. In some embodiments, an atomic object may be moved to an interaction zone, where the one or more functions may be performed on the atomic object. In various embodiments, the manipulation elements may be leveraged to enable performance of the one or more functions. In various embodiments, ferromagnetic films (also referred to herein as magnetic films) of the ferromagnet-integrated atomic object confinement apparatus 120 may be configured to generate and apply magnetic fields and magnetic field gradients to atomic objects to perform one or more functions.

The ferromagnetic films may comprise one or more permanent magnets. In various embodiments, one or more permanent magnets are provided transverse to a plane defined by a surface of the ferromagnet-integrated atomic object confinement apparatus 120. Alternatively or additionally in some embodiments, one or more permanent magnets are provided longitudinal to a plane defined by a surface of the ferromagnet-integrated atomic object confinement apparatus 120.

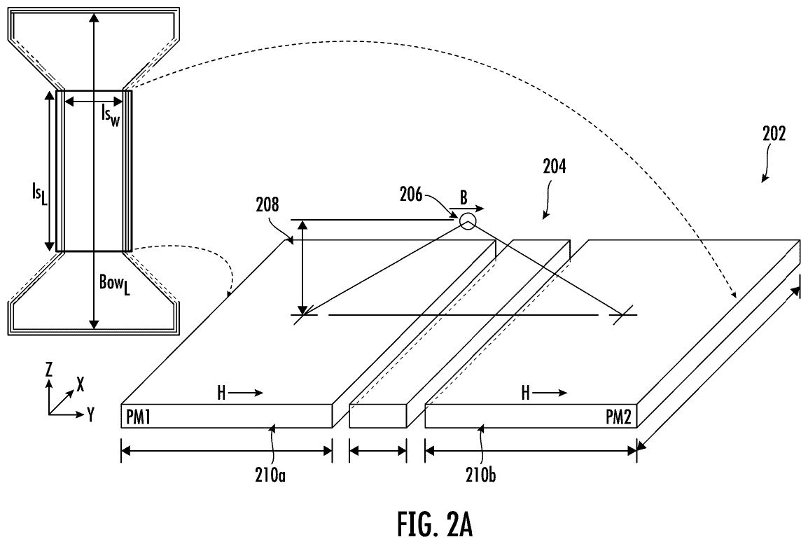

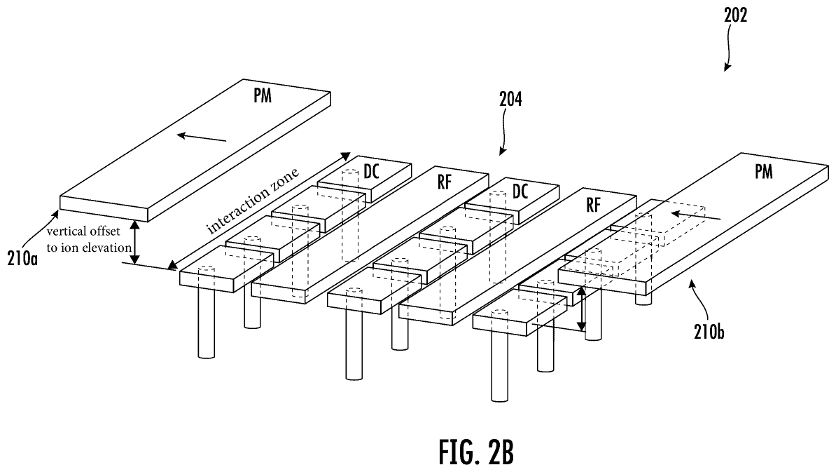

FIGS. 2a and 2b each provide a cross section of at least a portion of a ferromagnet-integrated atomic object confinement apparatus 120 in accordance with at least one example embodiment. Specifically, FIGS. 2a and 2b each provide a cross section of a top layer 202 (e.g., top metal layer) of a ferromagnet-integrated atomic object confinement apparatus 120 comprising a plurality of layers. FIG. 2a provides a cross section of a top layer 202 of a ferromagnet-integrated atomic object confinement apparatus 120 showing an example configuration according to at least one example embodiment. FIG. 2b provides a cross section of a top layer 202 of a ferromagnet-integrated atomic object confinement apparatus 120 showing another example configuration according to at least one example embodiment.

The top layer 202 of the plurality of layers of the ferromagnet-integrated atomic object confinement apparatus 120 may define or otherwise correspond to the surface of the ferromagnet-integrated atomic object confinement apparatus 120. In various embodiments, the top layer 202 of the ferromagnet-integrated atomic object confinement apparatus 120 comprises one or more electrodes 204 configured to generate the confining potential for confining atomic objects 206 within the confinement volume (e.g., confinement region) defined by the ferromagnet-integrated atomic object confinement apparatus 120. As described above, the confinement volume is a volume located proximate the surface of the ferromagnet-integrated atomic object confinement apparatus 120. In various embodiments, the confining potential is configured to confine atomic objects 206 in the confinement volume at an atomic object elevation 208 associated with the confinement volume. An atomic object elevation may describe a position of confined atomic objects above relative to a surface of the ferromagnet-integrated atomic object confinement apparatus. For example, the atomic object elevation may describe a height of the confined atomic objects above relative to the surface of the ferromagnet-integrated atomic object confinement apparatus 120.

In various embodiments, the ferromagnet-integrated atomic object confinement apparatus 120 comprises at least one ferromagnetic film integrated within and/or on the plurality of layers of the ferromagnet-integrated atomic object confinement apparatus 120. For example, ferromagnetic films may be integrated with the top layer and/or intermediate layers of the plurality of layers of the ferromagnet-integrated atomic object confinement apparatus 120. In various embodiments, the ferromagnetic film layers are configured to provide magnetic field and magnetic field gradient applied to one or more atomic objects confined in the confinement volume defined by the ferromagnet-integrated atomic object confinement apparatus 120. In various embodiments, the ferromagnetic films are configured to generate a quantization magnetic field that separates electronic states in a ground state manifold of magnetically-sensitive ions.

In various embodiments, the ferromagnetic films comprise permanent magnets. For example, one or more permanent magnets may be integrated into one or more layers of the ferromagnet-integrated atomic object confinement apparatus 120. In some embodiments, the permanent magnets generate a fixed uniform stray field at the atomic object elevation. In various embodiments, the permanent magnets are segmented in order to cant, tilt, and/or the like the generated magnetic field in accordance with the desired axis alignment. In various embodiments, the permanent magnet moment and stray field strength are determined based on the material species. It would be appreciated that the permanent magnets may be disposed within the ferromagnet-integrated atomic object confinement apparatus 120 in a variety of ways. For example, the permanent magnets may be arranged, orientated, and/or the like within the ferromagnet-integrated atomic object confinement apparatus 120 in a variety of ways.

As shown in FIGS. 2a and 2b, in some embodiments, a plurality of permanent magnets are disposed proximate to the top layer 202 of the ferromagnet-integrated atomic object confinement apparatus 120. Alternatively or additionally, a plurality of permanent magnets are disposed proximate to an intermediate layer of the ferromagnet-integrated atomic object confinement apparatus 120. In various embodiments, the plurality of permanent magnets are disposed or otherwise integrated within one or more chip stack elements. For example, one or more permanent magnets may be disposed or otherwise integrated in the ion trap (e.g., top surface and bottom surface regions thereof), interposer, spacers, subsequent layers, package, and/or the like.

In various embodiments, the plurality of permanent magnets comprise pinned permanent magnets, coupled permanent magnets, and/or the like. In various embodiments, the plurality of permanent magnets comprise planar Halbach array(s). In various embodiments, the permanent magnets are scaffolded. Alternatively or additionally in various embodiments, the permanent magnets are isolated and thermally set or coincidently pinned through a common exchange-biased layer. In various embodiments, the permanent magnets are strong remanent permanent magnet films. For example, the permanent magnets may have a high remanence and coercivity. In this regard, various embodiments monolithically integrate remanent magnetic field and gradient generation (e.g., generated by ferromagnetic films) into an atomic object confinement apparatus.

In some embodiments, the plurality of permanent magnets are disposed proximate to the top layer 202 such that they border the electrodes 204 in the top layer 202 of the ferromagnet-integrated atomic object confinement apparatus 120. As shown in FIGS. 2a and 2b, in some embodiments, a first permanent magnet 210a is disposed on a first side of the electrodes 204 of the top layer 202 of the ferromagnet-integrated atomic object confinement apparatus 120 and a second permanent magnet 210b is disposed on a second opposing side of the electrodes 204 of the top layer 202 of the ferromagnet-integrated atomic object confinement apparatus 120.

In some embodiments, and as shown in FIG. 2a, the plurality of permanent magnets are disposed within the ferromagnet-integrated atomic object confinement apparatus 120 such that they substantially align with the top layer 202 of the ferromagnet-integrated atomic object confinement apparatus 120 or otherwise form a portion of the top layer 202 of the ferromagnet-integrated atomic object confinement apparatus 120. For example, a plurality of thin permanent magnets (e.g., permanent magnet films) may be disposed in a plane defined by ferromagnet-integrated atomic object confinement apparatus 120 (e.g., the top layer 202 thereof) to generate magnetic fields and/or magnetic gradients with the confinement volume (e.g., at atomic object elevation) defined by the ferromagnet-integrated atomic object confinement apparatus 120. For example, as shown in FIG. 2a, the ferromagnet-integrated atomic object confinement apparatus 120 may lie in a x-y plane. As shown in FIG. 2a, the first permanent magnet 210a and the second permanent magnet 210b each substantially align with the electrodes 204 of the top layer 202 of the ferromagnet-integrated atomic object confinement apparatus 120. In this regard, the first permanent magnet 210a and the second permanent magnet 210b may lie in the same plane as the electrodes 204 of the top layer 202. In some embodiments, the plurality of permanent magnets define a magnetic orientation parallel to the plane defined by the top layer and rotated at an angle relative to an axis of the top layer to provide the magnetic field.

In some embodiments, and as shown in FIG. 2b, the plurality of permanent magnets are disposed within the ferromagnet-integrated atomic object confinement apparatus 120 such that they are vertically offset with respect to the top layer 202 of the ferromagnet-integrated atomic object confinement apparatus 120. For example, a plurality of permanent magnets may be disposed above the electrodes 204 of the top layer 202 to generate magnetic fields and/or magnetic gradients within the confinement volume (e.g., atomic object elevation) defined by the ferromagnet-integrated atomic object confinement apparatus 120. As shown in FIG. 2b, the first permanent magnet 210a and the second permanent magnet 210b are each vertically offset with respect to the electrodes 204 of top layer 202 of the ferromagnet-integrated atomic object confinement apparatus 120. In this regard, the plurality of permanent magnets may lie in the plane defined by the ferromagnet-integrated atomic object confinement apparatus 120 (e.g., top layer 202 thereof) with a vertical offset with respect to the top layer 202 of the ferromagnet-integrated atomic object confinement apparatus 120 such that they align with the atomic object elevation 208.

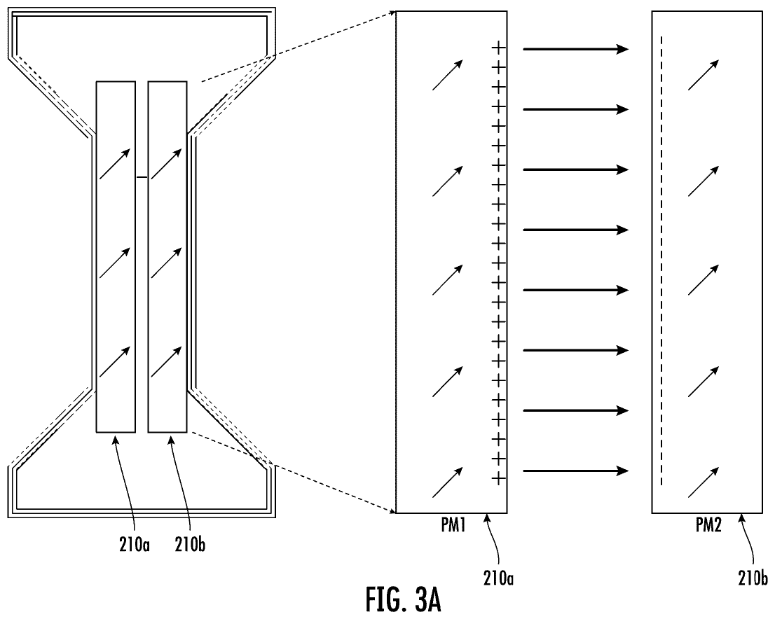

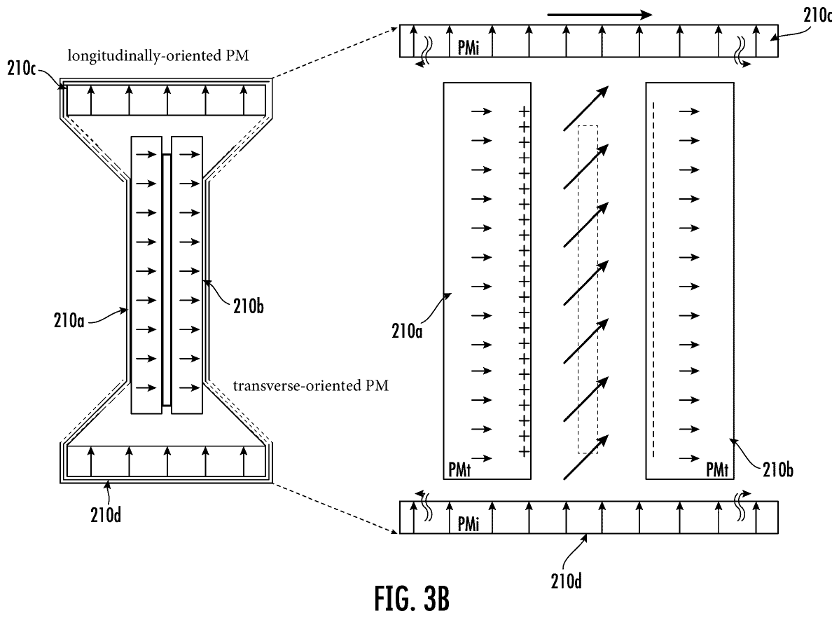

FIGS. 3a and 3b each provide an example on-axis ferromagnet integration in accordance with at least one example embodiment. Specifically, FIG. 3a illustrates a perpendicular magnetic orientation in accordance with at least one example embodiment and FIG. 3b illustrates a 45-degree magnetic orientation in accordance with at least one example embodiment. As shown in FIG. 3a, a first permanent magnet 210a and a second permanent magnet 210b may be configured to define a perpendicular magnetic orientation with respect to an axial direction of the ferromagnet-integrated atomic object confinement apparatus 120 so as to provide a perpendicular uniform stray magnetic field at the atomic object elevation 208. For example, the first permanent magnet 210a and the second permanent magnet 210b may be configured to define a perpendicular magnetic orientation with respect to an axial direction of the top layer 202 of the ferromagnet-integrated atomic object confinement apparatus 120. For example, the permanent magnets may be canted with respect to an axial direction of the ferromagnet-integrated atomic object confinement apparatus 120. In this regard, in some embodiments, a pair of permanent magnets may be configured to define a perpendicular magnetic orientation with respect to an axial direction of the ferromagnet-integrated atomic object confinement apparatus 120 (e.g., defined by the top layer 202 thereof) so as to provide a perpendicular uniform stray magnetic field. Different local magnetic orientations may enable a variety of functions that may not otherwise be possible.

In some embodiments, the ferromagnet-integrated atomic object confinement apparatus 120 comprises a permanent magnet configuration that enables a 45-degree oriented magnetic field vector with respect to the trap axis and/or 90-degree oriented magnetic field vector with respect to the beam line. In such embodiments, as shown in FIG. 3b, a first permanent magnet 210a, a second permanent magnet 210b, a third permanent magnet 210c, and a fourth permanent magnet 210d may be leveraged to generate a 45-degree field rotation with respect to the ferromagnet-integrated atomic object confinement apparatus 120 axis. As shown in FIG. 3b, the first permanent magnet 210a and the second permanent magnet 210b may be transversely orientated and the third permanent magnet 210c and fourth permanent magnet 210d may be longitudinally oriented. In this regard, a plurality of permanent magnets may be configured to define a 45-degree magnetic orientation with respect to an axial direction of the ferromagnet-integrated atomic object confinement apparatus 120 (e.g., top layer 202 thereof) to provide a 45-degree oriented magnetic field vector with respect to the trap axis and/or 90-degree oriented magnetic field vector with respect to the beam line.

It should be understood that the magnetic orientation described above with reference to FIGS. 3a and 3b are provided as non-limiting examples. For example, the perpendicular magnetic orientation, 45-degree magnetic orientation, 45-degree field rotation, and 45-degree oriented magnetic field vector are provided as examples and not intended to be limiting. The magnetic orientation may be different in other embodiments.

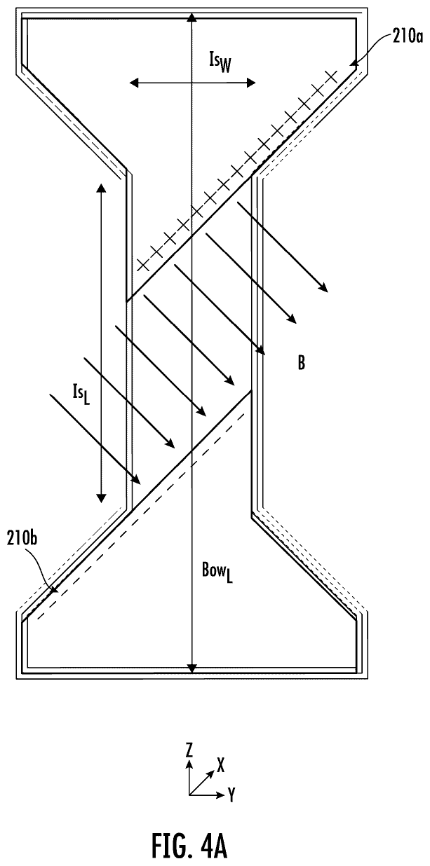

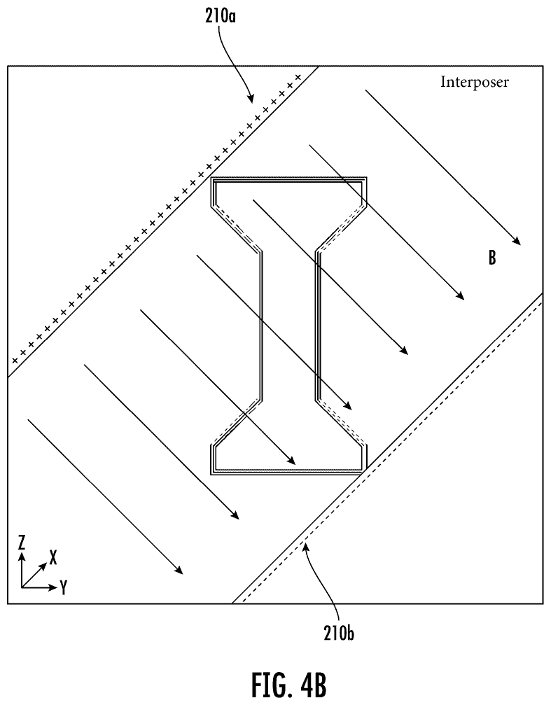

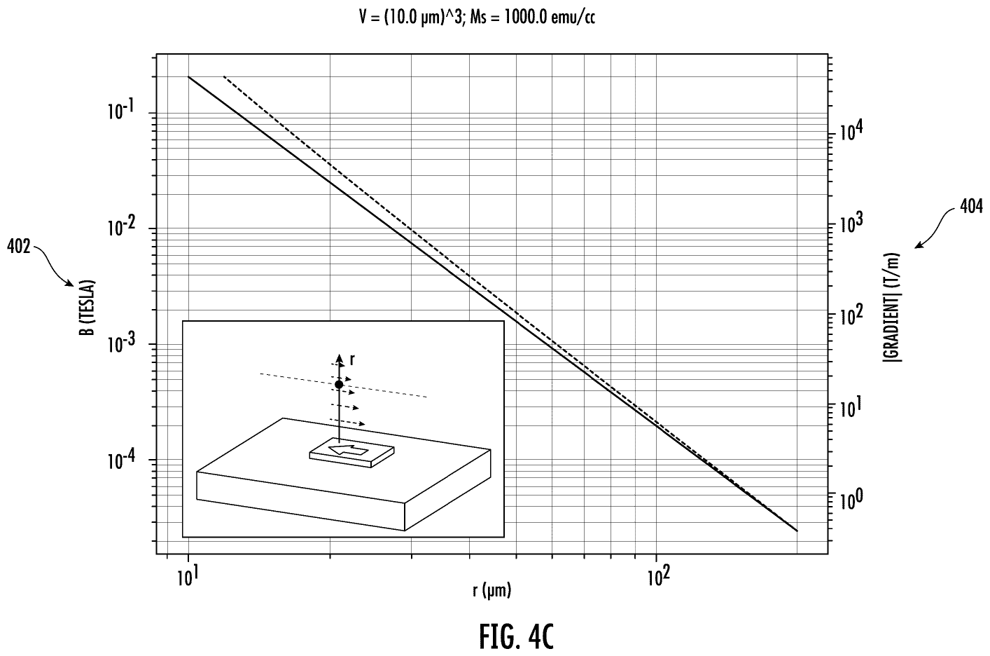

FIG. 4a provides an example off-axis ferromagnet integration in accordance with at least one example embodiment. As shown in FIG. 4a, in some embodiments, the ferromagnet-integrated atomic object confinement apparatus 120 includes permanent magnets that are integrated into the top layer 202 of the ferromagnet-integrated atomic object confinement apparatus 120 with built-in 45-degree field rotation with respect to the axial direction of the ferromagnet-integrated atomic object confinement apparatus 120. As shown in FIG. 4a, such example embodiments may be configured to provide, within the confinement volume, magnetic fields at a 45 degrees orientation. Alternatively or additionally, the ferromagnet-integrated atomic object confinement apparatus 120 includes permanent magnets that are integrated into one or more intermediate layers of the ferromagnet-integrated atomic object confinement apparatus 120 with built-in 45-degree field rotation with respect to the axial direction of the ferromagnet-integrated atomic object confinement apparatus 120.

It should be understood that the configuration of the permanent magnets described above with reference to FIG. 4a are provided as non-limiting examples. For example, the 45-degree field rotation or orientation described above are provided as examples and not intended to be limiting. The configuration of the permanent magnets may be different in other embodiments. For example, the permanent magnets may be configured and integrated within the ferromagnet-integrated atomic object confinement apparatus 120 in a variety of ways, such that magnetic fields at any desired orientation may be achieved.

FIG. 4b provides an example canted-axis ferromagnet integration in accordance with at least one example embodiment. As shown in FIG. 4b, in some embodiments, the ferromagnet-integrated atomic object confinement apparatus 120 may include permanent magnets that are integrated in an interposer associated with the ferromagnet-integrated atomic object confinement apparatus 120. For example, permanent magnets may be integrated within the top metal layers in the interposer to generate uniform magnetic field within the interposer. In such some embodiments, a 45 degrees static magnetic field may be generated. In such some embodiments, the edges where the magnetic field originates may be extended to a larger geometry (e.g., as compared to off-axis ferromagnet integration), which in turn provides broader uniformity of the generated magnetic field. In such some embodiments, high moment and/or thick ferromagnetic films (e.g., thin permanent magnets) may be leveraged to generate the desired field magnitude. It should be understood that the 45 degrees static magnetic field is provided as an example and not intended to be limiting.

In some embodiments, ferromagnetic films (e.g., permanent magnets) may be disposed in an interaction zone of the ferromagnet-integrated atomic object confinement apparatus 120, for example, to localize the generated magnetic field. For example, the confinement volume (e.g., confinement region) defined by the ferromagnet-integrated atomic object confinement apparatus may comprise one or more interaction zones, wherein the plurality of permanent magnets are positioned in the one or more interaction zones.

While the example embodiments described above depict a bow-tie shaped ferromagnet-integrated atomic object confinement apparatus 120 (e.g., bow-tie shaped surface ion trap), it should be understood that in other embodiments, the ferromagnet-integrated atomic object confinement apparatus 120 may have other shapes without departing from the scope of the present disclosure.

FIG. 4c provides a magnetic field and gradient plot in accordance with at least one example embodiment. As shown in FIG. 4c, the x-axis depicts the magnetic field 402 and the y-axis depicts the magnetic field gradient 404. In various embodiments, ferromagnetic films and magnetic structures are integrated in the top metal of the ferromagnet-integrated atomic object confinement apparatus 120 that generate a spatially dependent magnetic field gradient that promotes motional mode coupling of trapped ions in an ion crystal as illustrated in FIG. 4c (e.g., calculations showing magnetic field and magnetic field gradient as a function of distance away from the surface of the trap). In various embodiments, a magnetic structure may comprise a sequence of magnetic layers and non-magnetic layers (e.g., insulator, non-magnetic layer, or the like). For example, the magnetic structure may comprise a non-magnetic layer between two magnetic layers. In some embodiments, a magnetic field gradient is produced by a local ferromagnetic patterned device with magnetization and texture chosen to maximize the nonuniformity of the magnetic field at the location of the ion. In such some embodiments, based on the electronic states being magnetic field dependent, a magnetic field gradient couples ion motional states to electronic states. In some embodiments, magnetic structures that utilize pinning, exchange bias, or other magnetic anisotropy (e.g. shape anisotropy, Ruderman-Kittel-Kasuya-Yosida (RKKY) coupling as in a magnetic/non-magnetic-magnetic M/NM/M layer series) for the generation of stray fields and gradients are leveraged.

In various embodiments, one or more chips associated with the ferromagnet-integrated atomic object confinement apparatus 120 may be configured to generate magnetic fields. For example, one or more chips separate from the atomic object confinement apparatus may comprise one or more elements configured to generate magnetic fields. For example, the one or more chips may comprise magnetic films configured to generate magnetic fields leveraged by the ferromagnet-integrated atomic object confinement apparatus 120 to perform various functions with respect to atomic object confined in the confinement region.

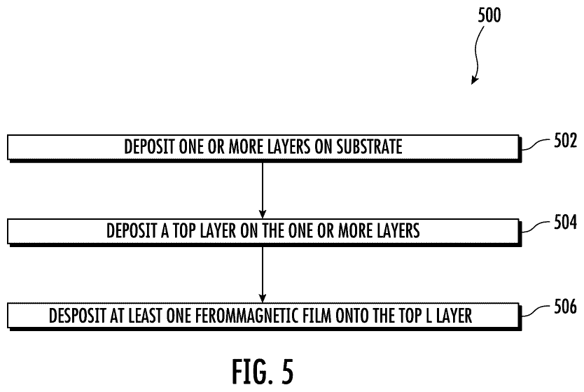

FIG. 5 provides a flowchart illustrating processes, procedures, operation, and/or the like for ferromagnet-integrated atomic object confinement apparatus in accordance with one example embodiment. Specifically, FIG. 5 depicts an example process 500 for fabricating ferromagnet-integrated atomic object confinement apparatus. Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence.

At step/operation 502, one or more layers are deposited on a substrate. For example, one or more metal layers, cladding layers, molds layers, and/or the like may be deposited on a substrate. The substrate may comprise any suitable material. For example, the substrate may comprise any material suitable for an integrated circuit and/or other applications. Non-limiting examples of materials that can be used to form the substrate include SiO2, Al2O3, SiN, SiC, Si, Ag, and/or the like.

At step/operation 504, a top layer is deposited on the one or more layers. In various embodiments, the top layer comprise one or more electrodes configured for generating confining potential for confining (e.g., trapping) atomic objects at an atomic object elevation above the top layer. In some embodiments, the top layer defines the surface of the ferromagnet-integrated atomic object confinement apparatus. The one or more layers may be deposited onto the substrate using one or more of a variety of techniques. For example, a layer may be deposited onto the substrate using spin-coating, roller coating, chemical vapor deposition, and/or other like. In one example, to form a layer on the surface of the substrate, one or more drops of the layer material may be deposited on the surface of the substrate. The substrate may then be spun, for example, at a high rate so that the one or more drops of the layer material become dispersed across the surface of the substrate. For example, the layer may be evenly dispersed across the surface of the substrate.

At step/operation 506, at least one ferromagnetic film is deposited. The at least one ferromagnetic film may be deposited in, on, within, adjacent, and/or the like relative to one or more layers of the ferromagnet-integrated atomic object confinement apparatus. For example, in some embodiments, the at least one ferromagnetic film is deposited onto the top layer. For example, one or more permanent magnets is deposited onto the top layer. For example, a plurality of permanent magnets may be deposited in a plane defined by the top layer. In some embodiments, the plurality of permanent magnets define a magnetic orientation parallel to the plane defined by the top layer and rotated at an angle relative to an axis of the top layer to provide the magnetic field. In some embodiments, the plurality of permanent magnets comprise a first permanent magnet and a second permanent magnet. In some embodiments, the plurality of permanent magnets is deposited such that they align with the electrodes of the top layer. For example, in some embodiments, the first permanent magnet is deposited on a first side of the electrodes of the top layer and the second permanent magnet is deposited on a second side of the electrodes of the top layers. In some embodiments, the plurality of permanent magnets is deposited such that they are vertically offset with respect to the top layer. For example, in some embodiments, the first permanent magnet is deposited on a first side of the electrodes of the top layer with a vertical offset (e.g., above the electrodes) and the second permanent magnet deposited on a second side of the electrodes of the top layer with a vertical offset (e.g., above the electrodes). In various embodiments, the plurality of permanent magnets are deposited in a plurality of layers. (e.g., one or more of surfaces of the atomic object confinement apparatus (e.g., ion trap), interposer, spacers, package layers, and/or the like). In various embodiments, a ferromagnetic layer may comprise a single slab permanent magnet layer or a patterned permanent magnet layer. In some embodiments, the plurality of permanent magnets comprise planar Halbach array(s).

In various embodiments, the ferromagnetic film(s) (e.g., comprising permanent magnet(s)) may be deposited using one or more of a variety of techniques. For example, in some embodiments, depositing the ferromagnetic film(s) comprises performing one or more of magnetron sputtering, atomic layer deposition, electron beam deposition, ion beam deposition, electroplating, or epitaxy (e.g., molecular beam epitaxy or other epitaxy methods). Alternatively or additionally, in some embodiments, depositing the ferromagnetic film(s) includes applying post-growth annealing under applied magnetic field, post-growth and post-patterning (e.g., local magnetization writing assisted by local heat or local magnetic fields), metallic plating (e.g., for thick films), epitaxial deposition (e.g., for crystalline-controlled films), and/or the like.

In some embodiments, the ferromagnet films comprise patterned permanent magnets. For example, the permanent magnets may be patterned for depositing on the top layer. In various embodiments, one or more of a variety of techniques may be leveraged for patterning the permanent magnets for integration into the ion trap. For example, subtractive patterning (e.g., wet etching, dry etching, polishing, and/or the like) may be leverage for patterning the magnetic materials (e.g., permanent magnets). As another example, additive patterning (e.g., masked deposition, patterned electroplating, area-selective deposition, and/or the like) may be leveraged for patterning the magnetic materials.

### Technical Advantages

Various embodiments provide technical solutions to the technical problems associated with atomic object confinement apparatuses and/or interaction with such atomic object confinement apparatuses. In various embodiments, apparatuses, systems, and methods provide for integration of magnetic fields and magnetic field gradients into atomic object confinement apparatuses, such as ion traps, that enable unique and novel ways of interaction with atomic objects (e.g., manipulation of quantum states in ions and atoms through interactions with magnetic fields and/or magnetic field gradients)-as opposed to, for example, off-chip magnetic fields and laser-based gates. Example embodiments integrate thin magnetic films (e.g., strong remanent permanent magnet films) into atomic object confinement apparatuses and/or interposers which produce magnetic fields and magnetic field gradients that enable motional mode coupling (e.g., interaction with atomic objects and/or manipulation of quantum states). For example, example embodiments integrate thin magnetic films into ion traps (e.g., the trap metal layers) and/or interposers to generate magnetic fields that separates electronic states in a ground state manifold of magnetically-sensitive ions and to generate magnetic field gradients for gates.

### Exemplary Controller

In various embodiments, an atomic object confinement apparatus 120 is incorporated into a system (e.g., a quantum computer 110) comprising a controller 30. In various embodiments, the controller 30 is configured to control various elements of the system (e.g., quantum computer 110). For example, the controller 30 may be configured to control the voltage sources 50, a cryogenic system and/or vacuum system controlling the temperature and pressure within the cryogenic and/or vacuum chamber 40, manipulation sources 60, cooling system, and/or other systems controlling the environmental conditions (e.g., temperature, humidity, pressure, and/or the like) within the cryogenic and/or vacuum chamber 40 and/or configured to manipulate and/or cause a controlled evolution of quantum states of one or more atomic objects confined by the atomic object confinement apparatus 120. In various embodiments, the controller 30 may be configured to receive signals from one or more optics collection systems.

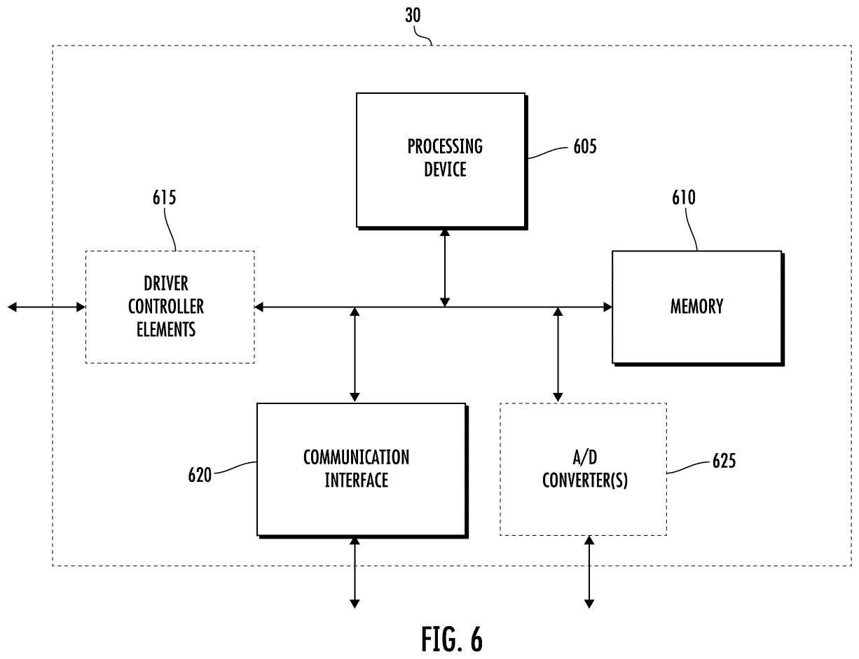

As shown in FIG. 6, in various embodiments, the controller 30 may comprise various controller elements including processing elements 605 (e.g., processing device), memory 610, driver controller elements 615, a communication interface 620, analog-digital converter elements 625, and/or the like. For example, the processing elements 605 may comprise programmable logic devices (CPLDs), microprocessors, coprocessing entities, application-specific instruction-set processors (ASIPs), integrated circuits, application specific integrated circuits (ASICs), field programmable gate arrays (FPGAs), programmable logic arrays (PLAs), hardware accelerators, other processing devices and/or circuitry, and/or the like. And/or controllers. The term circuitry may refer to an entirely hardware embodiment or a combination of hardware and computer program products. In an example embodiment, the processing element 605 of the controller 30 comprises a clock and/or is in communication with a clock.

For example, the memory 610 may comprise non-transitory memory such as volatile and/or non-volatile memory storage such as one or more of as hard disks, ROM, PROM, EPROM, EEPROM, flash memory, MMCs, SD memory cards, Memory Sticks, CBRAM, PRAM, FeRAM, RRAM, SONOS, racetrack memory, RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. In various embodiments, the memory 610 may store a queue of commands to be executed to cause a quantum algorithm and/or circuit to be executed (e.g., an executable queue), qubit records corresponding the qubits of quantum computer (e.g., in a qubit record data store, qubit record database, qubit record table, and/or the like), a calibration table, computer program code (e.g., in a one or more computer languages, specialized controller language(s), and/or the like), and/or the like. In an example embodiment, execution of at least a portion of the computer program code stored in the memory 610 (e.g., by a processing element 605) causes the controller 30 to perform one or more steps, operations, processes, procedures and/or the like described herein for providing manipulation signals to atomic object positions and/or collecting, detecting, capturing, and/or measuring indications of emitted signals emitted by atomic objects located at corresponding atomic object positions of the atomic object confinement apparatus 120.

In various embodiments, the driver controller elements 615 may include one or more drivers and/or controller elements each configured to control one or more drivers. In various embodiments, the driver controller elements 615 may comprise drivers and/or driver controllers. For example, the driver controllers may be configured to cause one or more corresponding drivers to be operated in accordance with executable instructions, commands, and/or the like scheduled and executed by the controller 30 (e.g., by the processing element 605). In various embodiments, the driver controller elements 615 may enable the controller 30 to operate a voltage sources 50, manipulation sources 60, cooling system, and/or the like. In various embodiments, the drivers may be laser drivers configured to operate one or manipulation sources 60 to generate manipulation signals; vacuum component drivers; drivers for controlling the flow of current and/or voltage applied to electrodes used for maintaining and/or controlling the trapping potential of the atomic object confinement apparatus 120 (and/or other drivers for providing driver action sequences to potential generating elements of the atomic object confinement apparatus); cryogenic and/or vacuum system component drivers; cooling system drivers, and/or the like. In various embodiments, the controller 30 comprises means for communicating and/or receiving signals from one or more optical receiver components (e.g., photodetectors of the optics collection system). For example, the controller 30 may comprise one or more analog-digital converter elements 625 configured to receive signals from one or more optical receiver components (e.g., a photodetector of the optics collection system), calibration sensors, and/or the like.

In various embodiments, the controller 30 may comprise a communication interface 620 for interfacing and/or communicating with a computing entity 10. For example, the controller 30 may comprise a communication interface 620 for receiving executable instructions, command sets, and/or the like from the computing entity 10 and providing output received from the quantum computer 110 (e.g., from an optical collection system) and/or the result of a processing the output to the computing entity 10. In various embodiments, the computing entity 10 and the controller 30 may communicate via a direct wired and/or wireless connection and/or via one or more wired and/or wireless networks 20.

### Exemplary Computing Entity

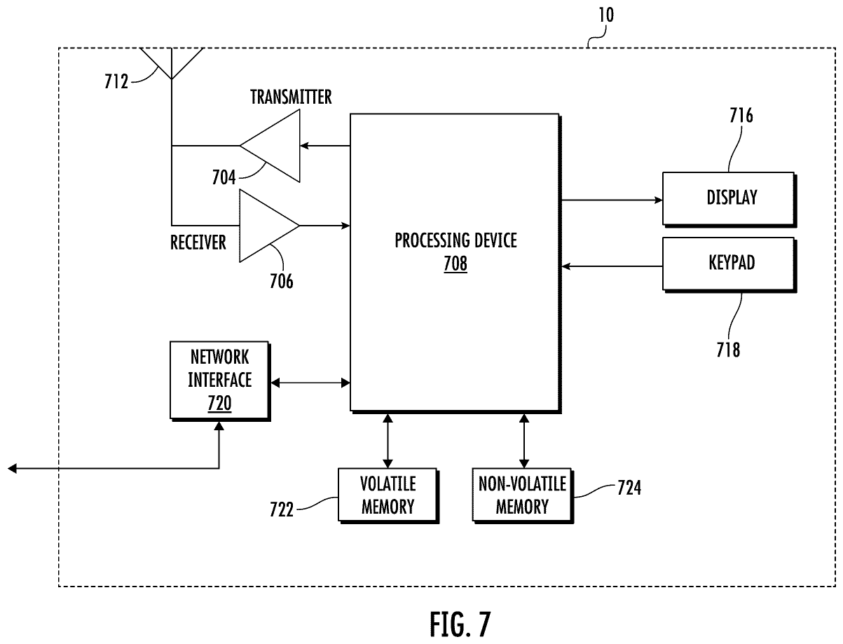

FIG. 7 provides an illustrative schematic representative of an example computing entity 10 that can be used in conjunction with embodiments of the present invention. In various embodiments, a computing entity 10 is configured to allow a user to provide input to the quantum computer 110 (e.g., via a user interface of the computing entity 10) and receive, display, analyze, and/or the like output from the quantum computer 110.

As shown in FIG. 7, a computing entity 10 can include an antenna 712, a transmitter 704 (e.g., radio), a receiver 706 (e.g., radio), and a processing element 708 (e.g., processing device) that provides signals to and receives signals from the transmitter 704 and receiver 706, respectively. The signals provided to and received from the transmitter 704 and the receiver 706, respectively, may include signaling information/data in accordance with an air interface standard of applicable wireless systems to communicate with various entities, such as a controller 30, other computing entities 10, and/or the like. In this regard, the computing entity 10 may be capable of operating with one or more air interface standards, communication protocols, modulation types, and access types. For example, the computing entity 10 may be configured to receive and/or provide communications using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 10 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 10 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

Via these communication standards and protocols, the computing entity 10 can communicate with various other entities using concepts such as Unstructured Supplementary Service information/data (USSD), Short Message Service (SMS), Multimedia Messaging Service (MMS), Dual-Tone Multi-Frequency Signaling (DTMF), and/or Subscriber Identity Module Dialer (SIM dialer). The computing entity 10 can also download changes, add-ons, and updates, for instance, to its firmware, software (e.g., including executable instructions, applications, program modules), and operating system.

In various embodiments, the computing entity 10 may comprise a network interface 720 for interfacing and/or communicating with the controller 30, for example. For example, the computing entity 10 may comprise a network interface 720 for providing executable instructions, command sets, and/or the like for receipt by the controller 30 and/or receiving output and/or the result of a processing the output provided by the quantum computer 110. In various embodiments, the computing entity 10 and the controller 30 may communicate via a direct wired and/or wireless connection and/or via one or more wired and/or wireless networks 20.

The computing entity 10 may also comprise a user interface device comprising one or more user input/output interfaces (e.g., a display 716 and/or speaker/speaker driver coupled to a processing element 708 and a touch screen, keyboard, mouse, and/or microphone coupled to a processing element 708). For instance, the user output interface may be configured to provide an application, browser, user interface, interface, dashboard, screen, webpage, page, and/or similar words used herein interchangeably executing on and/or accessible via the computing entity 10 to cause display or audible presentation of information/data and for interaction therewith via one or more user input interfaces. The user input interface can comprise any of a number of devices allowing the computing entity 10 to receive data, such as a keypad 718 (hard or soft), a touch display, voice/speech or motion interfaces, scanners, readers, or other input device. In embodiments including a keypad 718, the keypad 718 can include (or cause display of) the conventional numeric (0-9) and related keys (#, *), and other keys used for operating the computing entity 10 and may include a full set of alphabetic keys or set of keys that may be activated to provide a full set of alphanumeric keys. In addition to providing input, the user input interface can be used, for example, to activate or deactivate certain functions, such as screen savers and/or sleep modes. Through such inputs the computing entity 10 can collect information/data, user interaction/input, and/or the like.

The computing entity 10 can also include volatile storage or memory 722 and/or non-volatile storage or memory 724, which can be embedded and/or may be removable. For instance, the non-volatile memory may be ROM, PROM, EPROM, EEPROM, flash memory, MMCs, SD memory cards, Memory Sticks, CBRAM, PRAM, FeRAM, RRAM, SONOS, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. The volatile and non-volatile storage or memory can store databases, database instances, database management system entities, data, applications, programs, program modules, scripts, source code, object code, byte code, compiled code, interpreted code, machine code, executable instructions, and/or the like to implement the functions of the computing entity 10.

### Conclusion

Many modifications and other embodiments of the disclosure set forth herein will come to mind to one skilled in the art to which this disclosure pertains having the benefit of the teachings presented in the foregoing description and the associated drawings. Therefore, it is to be understood that the embodiments are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

While this specification contains many specific implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous.

Further, while this detailed description has set forth some embodiments of the present disclosure, the appended claims may cover other embodiments of the present disclosure which differ from the described embodiments according to various modifications and improvements. For example, while the description above provides an example atomic object confinement apparatus with integrated ferromagnetic films, it is noted that the scope of the present disclosure is not limited to the description above. Example embodiments of the present disclosure may be implemented in other apparatuses.

What is claimed is:

1. A ferromagnet-integrated atomic object confinement apparatus comprising:
a confinement region;
a first layer of a plurality of layers comprising one or more electrodes configured to generate a confining potential configured to confine one or more atomic objects in the confinement region at an atomic object elevation associated with the confinement region; and
at least one ferromagnetic film integrated with the plurality of layers, the at least one ferromagnetic film configured to apply magnetic fields and magnetic field gradients to the one or more atomic objects.

2. The ferromagnet-integrated atomic object confinement apparatus of claim 1, wherein the at least one ferromagnetic film is configured to generate a quantization magnetic field that separates electronic states in a ground state manifold of magnetically-sensitive ions.

3. The ferromagnet-integrated atomic object confinement apparatus of claim 1, wherein the at least one ferromagnetic film comprises a plurality of permanent magnets associated with the first layer.

4. The ferromagnet-integrated atomic object confinement apparatus of claim 3, wherein the plurality of permanent magnets comprise a planar Halbach array.

5. The ferromagnet-integrated atomic object confinement apparatus of claim 3, wherein the plurality of permanent magnets define a magnetic orientation parallel to a plane defined by the first layer and rotated at an angle relative to an axis of the first layer to provide the magnetic field.

6. The ferromagnet-integrated atomic object confinement apparatus of claim 3, wherein the plurality of permanent magnets comprise a first permanent magnet and a second permanent magnet that border the one or more electrodes.

7. The ferromagnet-integrated atomic object confinement apparatus of claim 3, wherein the confinement region comprises one or more interaction zones, wherein the plurality of permanent magnets are positioned in the one or more interaction zones.

8. The ferromagnet-integrated atomic object confinement apparatus of claim 1, wherein one or more ferromagnetic films are disposed in one or more subsequent layers with respect to the first layer.

9. The ferromagnet-integrated atomic object confinement apparatus of claim 1, further comprising an interposer, wherein the at least one ferromagnetic film comprises a plurality of permanent magnets disposed in the interposer.

10. The ferromagnet-integrated atomic object confinement apparatus of claim 1, wherein the first layer defines a surface of the ferromagnet-integrated atomic object confinement apparatus.

11. A quantum computing system comprising:
a ferromagnet-integrated atomic object confinement apparatus comprising:
a confinement region;
a first layer of a plurality of layers comprising one or more electrodes configured to generate a confining potential configured to confine one or more atomic objects in the confinement region at an atomic object elevation associated with the confinement region; and
at least one ferromagnetic film integrated with the plurality of layers, the at least one ferromagnetic film configured to apply magnetic fields and magnetic field gradients to the one or more atomic objects.

12. The quantum computing system of claim 11, wherein the at least one ferromagnetic film is configured to generate a quantization magnetic field that separates electronic states in a ground state manifold of magnetically-sensitive ions.

13. The quantum computing system of claim 11, wherein the at least one ferromagnetic film comprises a plurality of permanent magnets associated with the first layer.

14. The quantum computing system of claim 13, wherein the plurality of permanent magnets comprise a planar Halbach array.

15. The quantum computing system of claim 13, wherein the plurality of permanent magnets define a magnetic orientation parallel to a plane defined by the first layer and rotated at an angle relative to an axis of the first layer to provide the magnetic field.

16. The quantum computing system of claim 13, wherein the plurality of permanent magnets comprise a first permanent magnet and a second permanent magnet that border the one or more electrodes.

17. The ferromagnet-integrated atomic object confinement apparatus of claim 13, wherein the confinement region comprises one or more interaction zones, wherein the plurality of permanent magnets are positioned in the one or more interaction zones.

18. The quantum computing system of claim 11, wherein one or more ferromagnetic films are disposed in one or more subsequent layers with respect to the first layer.

19. A method of fabricating a ferromagnet-integrated atomic object confinement apparatus, the method comprising:
depositing one or more layers on a substrate;
depositing a top layer on the one or more layers, the top layer comprising one or more electrodes; and
depositing at least one ferromagnetic film.

20. The method of claim 19, wherein depositing the at least one ferromagnetic film comprises performing one or more of magnetron sputtering, atomic layer deposition, electron beam deposition, ion beam deposition, electroplating, or epitaxy.
